(19) United States
(12) Patent Application Publication
(10) Pub. No.: US 2020/0091061 A1
(43) Pub. Date: Mar. 19, 2020

(54) ELECTRONIC MODULE AND SWITCHING POWER SUPPLY

(71) Applicant: Murata Manufacturing Co., Ltd., Nagaokakyo-shi (JP)

(72) Inventor: Norifumi KOBAYASHI, Nagaokakyo-shi (JP)

(21) Appl. No.: 16/690,196

(22) Filed: Nov. 21, 2019

Related U.S. Application Data
(63) Continuation of application No. PCT/JP2019/022557, filed on Jun. 6, 2019.

(30) Foreign Application Priority Data
Jun. 23, 2018 (JP) 2018-119396

(51) Int. Cl. H01L 23/498; H01L 23/00; H01L 23/64; H02M 3/158; H02M 1/34

(52) U.S. Cl. CPC H01L 23/49844; H01L 24/32; H01L 23/49822; H01L 23/642; H01L 23/645; H02M 3/158; H02M 2001/346; H01L 2224/32227; H01L 2924/13091; H01L 2924/19041; H01L 2924/19042; H01L 2924/19103; H01L 2924/14252; H02M 1/34

(57) ABSTRACT

An electronic module includes a multilayer substrate and an FET. The multilayer substrate includes stacked substrate layers. First and second outer electrodes, a third outer electrode, and first, second, and third connecting electrodes on the multilayer substrate. The first outer electrodes and the first connecting electrode are connected to each other. The second outer electrodes and the second connecting electrode are connected to each other. The third outer electrode and the third connecting electrode are connected to each other. Terminal electrodes of the FET are connected to the first, second, and third connecting electrodes. A second capacitor electrode is between the corresponding layers of the multilayer substrate. A capacitor is defined by electrostatic capacitance between the first connecting electrode and the second capacitor electrode. An inductor is defined by via-conductors connecting the second capacitor electrode and the second connecting electrode. A snubber circuit is defined by the capacitor and the inductor.

### CROSS REFERENCE TO RELATED APPLICATIONS

This application claims the benefit of priority to Japanese Patent Application No. 2018-119396 filed on Jun. 23, 2018 and is a Continuation Application of PCT Application No. PCT/JP2019/022557 filed on Jun. 6, 2019. The entire contents of each application are hereby incorporated herein by reference.

### BACKGROUND OF THE INVENTION

### 1. Field of the Invention

The present invention relates to an electronic module in which a switching element is mounted on a multilayer substrate. More particularly, the present invention relates to an electronic module in which a snubber circuit is provided in a multilayer substrate.

The present invention also relates to a switching power supply including the electronic module.

### 2. Description of the Related Art

In some electronic devices, such as switching power supplies, including a switching element, a snubber circuit is disposed to reduce switching noise. For example, Japanese Unexamined Patent Application Publication No. 2003-224975 discloses a switching power supply including a snubber circuit. A switching power supply 1000 disclosed in Japanese Unexamined Patent Application Publication No. 2003-224975 is shown in FIG. 14. FIG. 14 is an equivalent circuit diagram of the switching power supply 1000.

The switching power supply 1000 includes a snubber circuit 106 defined by diodes 101 and 102, a capacitor 103, an inductor 104, and a resistor 105. A snubber circuit may be configured in various manners and is not restricted to the circuit configuration shown in the switching power supply 1000. Some snubber circuits are defined by an inductor and a resistor or an inductor and a capacitor without using diodes.

Typically, the diodes 101 and 102, the capacitor 103, the inductor 104, and the resistor 105 of the snubber circuit 106 are mounted on a substrate (not shown), together with an FET (Field effect transistor) 107, which is a switching element, and another electronic component 108.

In an electronic device, such as a switching power supply, if electronic elements of a snubber circuit are defined by individual electronic components, more components are required in the electronic device, thus making the manufacturing of the electronic device complicated. Additionally, if the electronic components of the snubber circuit are mounted on a substrate, together with a switching element and another electronic component, a large substrate is required.

### SUMMARY OF THE INVENTION

Preferred embodiments of the present invention provide electronic modules in each of which electronic elements of a snubber circuit are integrated within a multilayer substrate, and a switching element is mounted on the multilayer substrate.

An electronic module according to a preferred embodiment of the present invention includes a multilayer substrate and a switching element. The multilayer substrate includes a plurality of substrate layers stacked on each other, first and second main surfaces opposing each other, and at least one side surface connecting the first and second main surfaces. The switching element includes a plurality of terminal electrodes and is mounted on the second main surface of the multilayer substrate. First, second, and third outer electrodes are provided on the first main surface. First, second, and third connecting electrodes are provided on the second main surface. The first outer electrode and the first connecting electrode are electrically connected to each other by at least one first connecting conductor. The second outer electrode and the second connecting electrode are electrically connected to each other by at least one second connecting conductor. The third outer electrode and the third connecting electrode are electrically connected to each other by at least one third connecting conductor. The corresponding terminal electrodes of the switching element are connected to the first, second, and third connecting electrodes. The first connecting electrode also defines and functions as a first capacitor electrode. A second capacitor electrode is provided between corresponding layers of the substrate layers of the multilayer substrate. A capacitor is defined by electrostatic capacitance generated between the first capacitor electrode and the second capacitor electrode. The second capacitor electrode and the second connecting electrode are electrically connected to each other by at least one fourth connecting conductor. An inductor is defined by the at least one fourth connecting conductor. The capacitor and the inductor define a snubber circuit.

In an electronic module according to a preferred embodiment of the present invention, the first connecting electrode also defines and functions as the first capacitor electrode defining the capacitor of the snubber circuit. Thus, the height of the electronic module is smaller than that of the configuration in which a first capacitor electrode, which is provided separately from the first connecting electrode, is provided between layers of the multilayer substrate.

In an electronic module according to a preferred embodiment of the present invention, at least one of the substrate layers may be a magnetic layer made of a magnetic material, and the fourth connecting conductor may pass through the at least one magnetic layer. This configuration is able to increase the inductance value of the inductor of the snubber circuit. In other words, even if the fourth connecting conductor has a short length, a sufficient inductance value is able to be obtained.

The area of the first connecting electrode, which also defines and functions as the first capacitor electrode, may be larger than that of the second connecting electrode and that of the third connecting electrode. This configuration is able to increase the electrostatic capacitance of the capacitor of the snubber circuit. It is also possible to efficiently dissipate heat generated by the switching element by letting heat pass through the first connecting electrode (first capacitor electrode).

The switching element may be an FET including a drain electrode, a source electrode, and a gate electrode as the terminal electrodes. The drain electrode may be electrically connected to the first connecting electrode, the source electrode may be electrically connected to the second connecting electrode, and the gate electrode may be electrically connected to the third connecting electrode. Alternatively, the switching element may be configured in the following manner. The switching element may be an FET including a drain electrode, a source electrode, and a gate electrode as the terminal electrodes. The source electrode may be electrically connected to the first connecting electrode, the drain electrode may be electrically connected to the second connecting electrode, and the gate electrode may be electrically connected to the third connecting electrode. However, in the electronic modules according to preferred embodiments of the present invention, the switching element is not limited to an FET and may be another type of switching element, such as a bipolar transistor.

The length of the fourth connecting conductor may be greater than the distance between the first capacitor electrode and the second capacitor electrode. This configuration is able to increase the inductance value of the inductor of the snubber circuit.

The first connecting conductor may pass through the at least one magnetic layer. The second connecting conductor may pass through the at least one magnetic layer. In this case, the first and second connecting conductors each define a bead element which passes through the magnetic layer and substantially stops noise from passing through the magnetic layer. In an electronic device, such as a switching power supply, a sharp noise waveform is superposed on an output waveform immediately after the electronic device is switched ON. Such a noise waveform is able to be made less sharp by the first and second connecting conductors and can be reduced or eliminated.

The third connecting conductor may be provided on the corresponding side surface of the multilayer substrate so as to electrically connect the third outer electrode and the third connecting electrode. With this configuration, it is possible to reduce or minimize unwanted inductance components to be generated in the third connecting conductor. The third connecting conductor does not pass through the magnetic layer and does not define a bead element. Thus, if a control signal to control the switching element is transmitted from the third outer electrode to the third connecting electrode via this third connecting conductor, it is not attenuated.

The multilayer substrate may include, as at least one of the substrate layers, at least one of a dielectric layer covering the entirety or substantially the entirety of a surface area of the multilayer substrate and a dielectric layer covering a portion of a surface area of the multilayer substrate. The dielectric layer included in the multilayer substrate may be disposed between the first capacitor electrode and the second capacitor electrode which define the capacitor. This configuration is able to increase the electrostatic capacitance of the capacitor forming the snubber circuit.

A switching power supply may be provided by mounting an electronic module according to a preferred embodiment of the present invention on a substrate. In this case, it is possible to reduce the number of components of the switching power supply, to decrease the area of the substrate, and to simplify the manufacturing process.

By using electronic modules according to preferred embodiments of the present invention, electronic devices, such as a switching power supply including a switching element and a snubber circuit, are able to be defined with fewer components. Using the electronic modules also decreases the area of a substrate of an electronic device including a switching element and a snubber circuit. Using the electronic modules also simplifies the manufacturing process of an electronic device including a switching element and a snubber circuit.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a perspective view of an electronic module 100 according to a first preferred embodiment of the present invention, and FIG. 1B is an exploded perspective view of the electronic module 100.

FIG. 2 is a sectional view of the electronic module 100.

FIG. 3 is an exploded perspective view of a multilayer substrate 1 of the electronic module 100.

FIG. 4 is an equivalent circuit diagram of the electronic module 100.

FIG. 5A is a plan view of a switching power supply 200 according to a second preferred embodiment of the present invention, and FIG. 5B is an equivalent circuit diagram of the switching power supply 200.

FIG. 6 is an exploded perspective view of an electronic module 300 according to a third preferred embodiment of the present invention.

FIG. 7A is an exploded perspective view of an electronic module 400 according to a fourth preferred embodiment of the present invention, and FIG. 7B is a sectional view of the electronic module 400.

FIG. 8 is an equivalent circuit diagram of the electronic module 400.

FIG. 9 is a sectional view of an electronic module 500 according to a fifth preferred embodiment of the present invention.

FIG. 10 is a sectional view of an electronic module 600 according to a sixth preferred embodiment of the present invention.

FIG. 11 is a sectional view of an electronic module 700 according to a seventh preferred embodiment of the present invention.

FIG. 12 is an exploded perspective view of a multilayer substrate 1 of an electronic module 800 according to an eighth preferred embodiment of the present invention.

FIG. 13 is an equivalent circuit diagram of the electronic module 800.

FIG. 14 is an equivalent circuit diagram of a switching power supply 1000 disclosed in Japanese Unexamined Patent Application Publication No. 2003-224975.

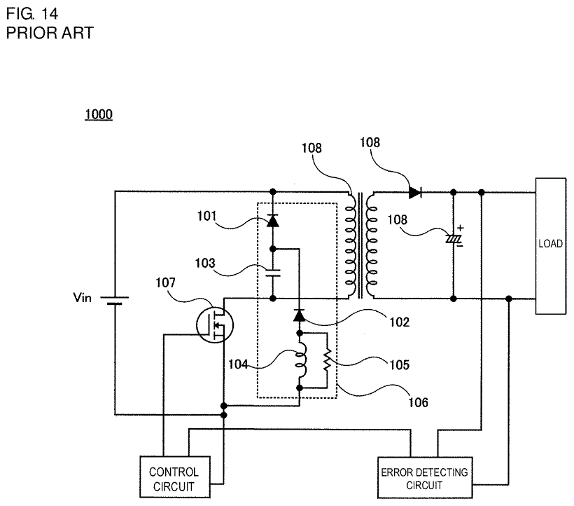

### DETAILED DESCRIPTION OF THE PREFERRED EMBODIMENTS

Preferred embodiments of the present invention will be described in detail below with reference to the drawings.

Hereinafter, individual preferred embodiments will be described below. Each preferred embodiment merely illustrates an example of a preferred embodiment of the present invention, and the present invention is not restricted thereto. Different preferred embodiments may suitably be combined with each other, and the content of such a combined preferred embodiment is encompassed within the present invention. The drawings are provided for better understanding of the specification and some drawings are schematically shown. The size ratio of each component or the size ratio of one component to that of another component shown in the drawings may not match that described in the specification. Some components described in the specification may not be shown in the drawings or may be shown as a fewer number.

### First Preferred Embodiment

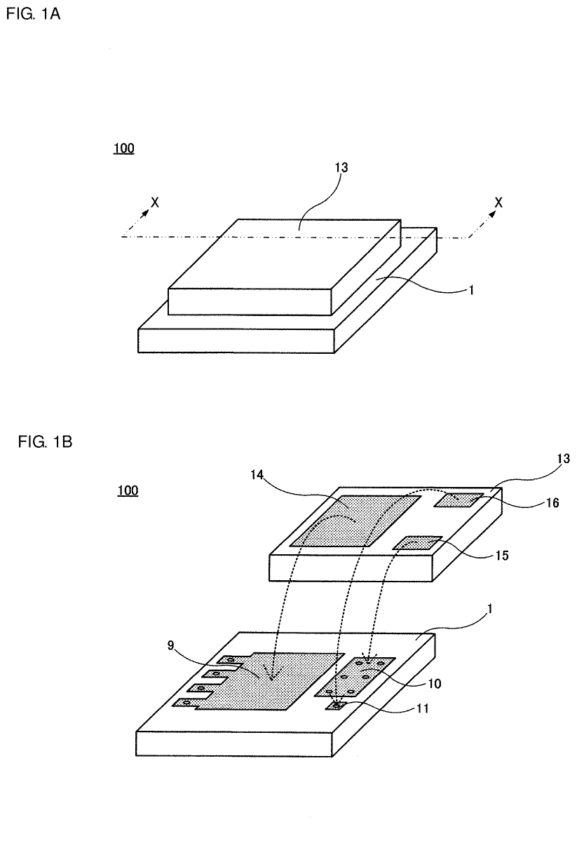

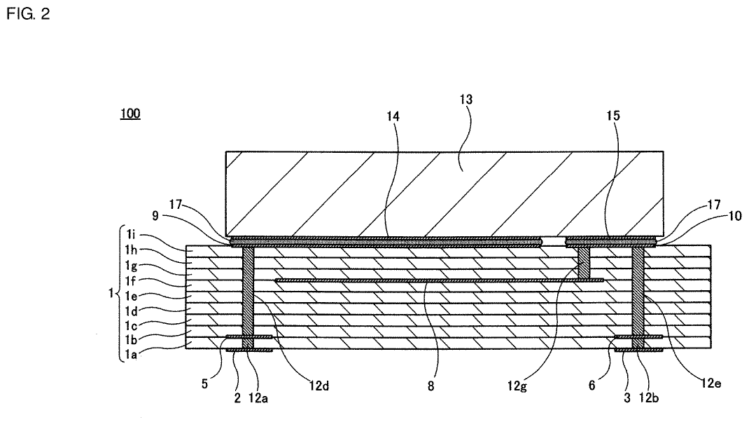

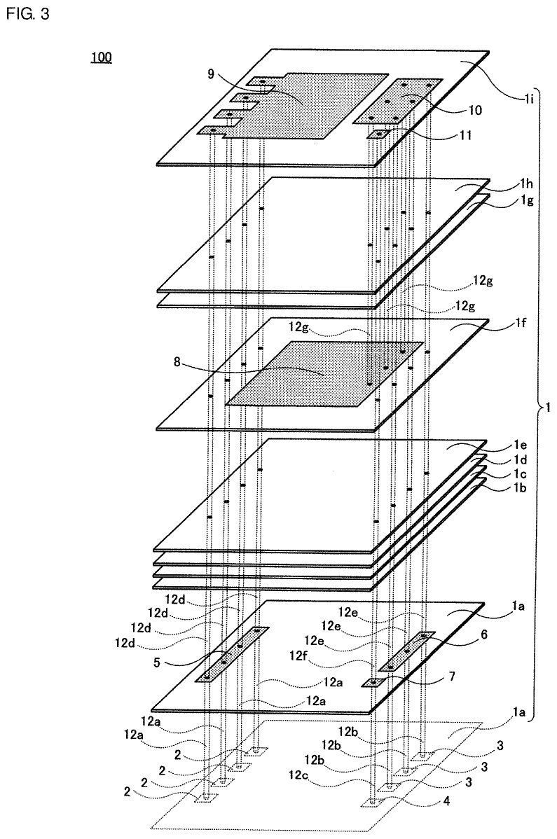

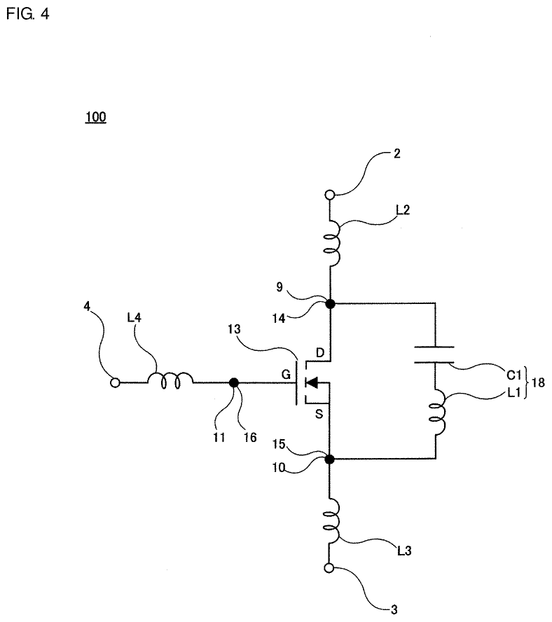

An electronic module 100 according to a first preferred embodiment of the present invention is shown in FIGS. 1A, 1B, and FIGS. 2, 3, and 4. FIG. 1A is a perspective view of the electronic module 100. FIG. 1B is an exploded perspective view of the electronic module 100 and illustrates the state in which an FET 13 is separated from a multilayer substrate 1 and solder 17 is not shown. FIG. 2 is a sectional view of the electronic module 100 taken along the long dashed dotted line X-X in FIG. 1A. FIG. 3 is an exploded perspective view of the multilayer substrate 1 of the electronic module 100 and illustrates separated nine individual substrate layers 1a through 1i. In FIG. 3, first outer electrodes 2, second outer electrodes 3, and a third outer electrode 4 provided on the lower main surface of the bottommost substrate layer 1a are also indicated by the broken lines. FIG. 4 is an equivalent circuit diagram of the electronic module 100.

The electronic module 100 includes the multilayer substrate 1.

As shown in FIGS. 2 and 3, the multilayer substrate 1 includes nine substrate layers 1a through 1i stacked on each other. In the present preferred embodiment, all of the substrate layers 1a through 1i are preferably magnetic layers.

On the lower main surface of the substrate layer 1a (first main surface of the multilayer substrate 1), the four first outer electrodes 2, the three second outer electrodes 3, and the single third outer electrode 4 are provided.

On the upper main surface of the substrate layer 1a, a first relay electrode 5, a second relay electrode 6, and a third relay electrode 7 are provided.

On the upper main surface of the substrate layer 1f, a second capacitor electrode 8 is provided.

On the upper main surface of the substrate layer 1i (second main surface of the multilayer substrate 1), a first connecting electrode 9, a second connecting electrode 10, and a third connecting electrode 11 are provided. The first connecting electrode 9 also defines and functions as a first capacitor electrode.

In the present preferred embodiment, the areas of the first connecting electrode 9, the second connecting electrode 10, and the third connecting electrode 11 are different from each other and are larger in order of the first, second, and third connecting electrodes 9 through 11.

Silver, for example, is preferably used as the principal component of the first outer electrodes 2, the second outer electrodes 3, the third outer electrode 4, the first relay electrode 5, the second relay electrode 6, the third relay electrode 7, the second capacitor electrode 8, the first connecting electrode 9, the second connecting electrode 10, and the third connecting electrode 11. However, the material for these electrodes is not limited to silver, and copper or another metal, for example, may be used as the principal component. These electrodes may include multiple metals, which may be an alloy.

One or multiple layers of plating may be applied to the surfaces of the first outer electrodes 2, the second outer electrodes 3, the third outer electrode 4, the first connecting electrode 9, the second connecting electrode 10, and the third connecting electrode 11. A material may be used for plating, and nickel, gold, and platinum, for example, may preferably be used.

Four via-conductors 12a, which are a first connecting conductor, three via-conductors 12b, which are a second connecting conductor, and one via-conductor 12c, which is a third connecting conductor pass between the two main surfaces of the substrate layer 1a. The number of via-conductors 12a (first connecting conductor), that of via-conductors 12b (second connecting conductor), and that of via-conductors 12c (third connecting conductor) are not restricted to those described above and may be larger or smaller. In the present preferred embodiment, the via-conductors of each connecting conductor are formed continuously and linearly. However, the via-conductors of each connecting conductor may be formed at different positions as viewed from above and be connected to each other by using a planar conductor extending in the surface direction between substrate layers.

The four first outer electrodes 2 and the first relay electrode 5 are electrically connected to each other by the via-conductors 12a (first connecting conductor).

The three second outer electrodes 3 and the second relay electrode 6 are electrically connected to each other by the via-conductors 12b (second connecting conductor).

The third outer electrode 4 and the third relay electrode 7 are electrically connected to each other by the via-conductor 12c (third connecting conductor).

Four via-conductors 12d, which are the first connecting conductor, three via-conductors 12e, which are the second connecting conductor, and one via-conductor 12f, which is the third connecting conductor pass between the two main surfaces of each of the substrate layers 1b through 1i. The number of via-conductors 12d (first connecting conductor), that of via-conductors 12e (second connecting conductor), and that of via-conductors 12f (third connecting conductor) are not restricted to those described above and may be larger or smaller.

The first relay electrode 5 and the first connecting electrode 9 are electrically connected to each other by the via-conductors 12d (first connecting conductor).

The second relay electrode 6 and the second connecting electrode 10 are electrically connected to each other by the via-conductors 12e (second connecting conductor).

The third relay electrode 7 and the third connecting electrode 11 are electrically connected to each other by the via-conductor 12f (third connecting conductor).

Three via-conductors 12g, which are a fourth connecting conductor, pass between the two main surfaces of each of the substrate layers 1g through 1i. The number of via-conductors 12g (fourth connecting conductor) is not restricted to three and may be larger or smaller.

The second capacitor electrode 8 and the second connecting electrode 10 are electrically connected to each other by the via-conductors 12g (fourth connecting conductor).

Silver, for example, may preferably be used as the principal component of the via-conductors 12a through 12g. However, the material for the via-conductors 12a through 12g is not limited to silver, and copper or another metal, for example, may be used as the principal component. These via-conductors may include multiple metals, which may be an alloy.

As shown in FIGS. 1A, 1B, and FIG. 2, the FET 13, which is a switching element, is mounted on the upper main surface (second main surface) of the multilayer substrate 1. In the present preferred embodiment, an N-channel FET, for example, is preferably used as the FET 13. However, a P-channel FET may be used as the FET 13.

On the lower main surface of the FET 13, a drain electrode 14, a source electrode 15, and a gate electrode 16 are provided. By using the solder 17, the drain electrode 14 of the FET 13 is connected to the first connecting electrode 9 of the multilayer substrate 1, the source electrode 15 of the FET 13 is connected to the second connecting electrode 10 of the multilayer substrate 1, and the gate electrode 16 of the FET 13 is connected to the third connecting electrode 11 of the multilayer substrate 1.

The electronic module 100 having the above-described structure can be manufactured by a manufacturing method which has been typically used for an electronic module.

An equivalent circuit of the electronic module 100 is shown in FIG. 4.

The electronic module 100 includes the first outer electrodes 2, the second outer electrodes 3, and the third outer electrode 4.

A second inductor L2 is connected between the first outer electrodes 2 and the first connecting electrode 9. The second inductor L2 is defined by a conductive path linking the via-conductors 12a, the first relay electrode 5, and the via-conductors 12d.

The drain electrode 14 of the FET 13 is connected to the first connecting electrode 9.

A third inductor L3 is connected between the second outer electrodes 3 and the second connecting electrode 10. The third inductor L3 is defined by a conductive path linking the via-conductors 12b, the second relay electrode 6, and the via-conductors 12e.

The source electrode 15 of the FET 13 is connected to the second connecting electrode 10.

A fourth inductor L4 is connected between the third outer electrode 4 and the third connecting electrode 11. The fourth inductor L4 is defined by a conductive path linking the via-conductor 12c, the third relay electrode 7, and the via-conductor 12f.

The gate electrode 16 of the FET 13 is connected to the third connecting electrode 11.

A snubber circuit 18 including a capacitor C1 and a first inductor L1 that are connected in series with each other is connected in parallel with the FET 13. More specifically, the snubber circuit 18 including the series-connected capacitor C1 and first inductor L1 is connected between the drain electrode 14 (first connecting electrode 9) and the source electrode 15 (second connecting electrode 10) of the FET 13.

The capacitor C1 is defined by electrostatic capacitance generated between the first capacitor electrode (first connecting electrode 9) and the second capacitor electrode 8.

The first inductor L1 includes the via-conductors 12g, which is the fourth connecting conductor, electrically connecting the second capacitor electrode 8 and the source electrode 15 (second connecting electrode 10).

The electronic module 100 having the above-described structure and the above-described equivalent circuit achieves the following advantages.

The electronic module 100 is able to reduce or eliminate switching noise by using the snubber circuit 18 including the series-connected capacitor C1 and first inductor L1.

In the electronic module 100, the via-conductors 12g defining the fourth connecting conductor, which connects the second capacitor electrode 8 and the second connecting electrode 10, pass through the substrate layers 1g through 1i, which are magnetic layers made of a magnetic material. The first inductor L1 of the snubber circuit 18 thus has a large inductance value.

In the electronic module 100, the first connecting electrode 9 also defines and functions as the first capacitor electrode defining the capacitor C1 of the snubber circuit 18. Thus, the height of the electronic module 100 is smaller than that of the configuration in which a first capacitor electrode, which is provided separately from the first connecting electrode 9, is provided between layers of the multilayer substrate 1.

In the electronic module 100, the via-conductors 12a and 12d defining the first connecting conductor (second inductor L2), which connect the first outer electrodes 2 and the first connecting electrode 9, and the via-conductors 12b and 12e defining the second connecting conductor (third inductor L3), which connect the second outer electrodes 3 and the second connecting electrode 10, pass through the substrate layers 1a through 1i, which are magnetic layers made of a magnetic material. The via-conductors 12a, 12d, 12b, and 12e thus define bead elements. In an electronic device, such as a switching power supply, a sharp noise waveform is superposed on an output waveform immediately after the electronic device is switched ON. If the electronic module 100 is used in an electronic device, such a noise waveform can be made less sharp by the first connecting conductor (second inductor L2) and the second connecting conductor (third inductor L3) and can be reduced or eliminated.

In the electronic module 100, the area of the first connecting electrode 9, which also defines and functions as the first capacitor electrode, is larger than that of the second connecting electrode 10 and that of the third connecting electrode 11. This configuration is able to increase the electrostatic capacitance of the capacitor C1 of the snubber circuit 18. This configuration can also efficiently dissipate heat generated by the FET 13 by letting heat pass through the first connecting electrode 9.

By using the electronic module 100, an electronic device, such as a switching power supply including a switching element and a snubber circuit, can be provided with fewer components. Using the electronic module 100 can also decrease the area of the substrate of an electronic device, such as a switching power supply including a switching element and a snubber circuit. Using the electronic module 100 can also simplify the manufacturing process of an electronic device, such as a switching power supply including a switching element and a snubber circuit.

### Second Preferred Embodiment

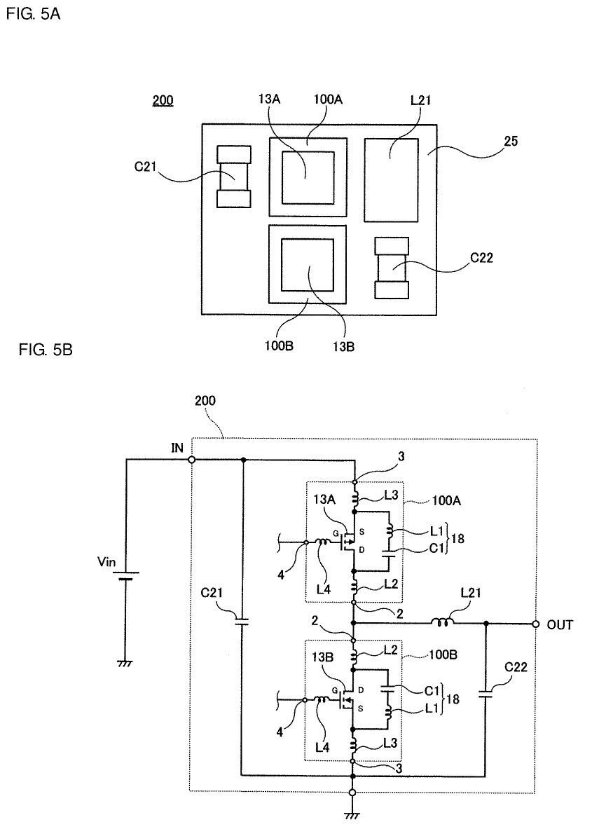

A switching power supply 200 according to a second preferred embodiment of the present invention is shown in FIGS. 5A and 5B. FIG. 5A is a plan view of the switching power supply 200. FIG. 5B is an equivalent circuit diagram of the switching power supply 200.

The switching power supply 200 is a DC-to-DC converter.

The switching power supply 200 includes a substrate 25. A preferable material may be used for the substrate 25. The substrate 25 may be a ceramic substrate or a resin substrate, for example. The substrate 25 may be a single-layer substrate or a multilayer substrate. Predetermined outer electrodes, connecting electrodes, and wiring are provided on the substrate 25, though they are not shown.

On the substrate 25, two electronic modules 100A and 100B, two capacitors C21 and C22, and one inductor L21 are mounted.

The electronic module 100 of the above-described first preferred embodiment is used for each of the two electronic modules 100A and 100B. A P-channel FET is preferably used as an FET 13A of the electronic module 100A, while an N-channel FET is preferably used as an FET 13B of the electronic module 100B.

The switching power supply 200 is represented by an equivalent circuit shown in FIG. 5B. This will be explained more specifically. The electronic module 100A including the FET 13A and the electronic module 100B including the FET 13B are connected between an input terminal IN and a ground. A node between the electronic modules 100A and 100B is connected to an output terminal OUT via the inductor L21. The input terminal IN is connected to a ground via the capacitor C21. The output terminal OUT is connected to a ground via the capacitor C22.

The switching power supply 200 uses the electronic module 100 of the first preferred embodiment as each of the electronic modules 100A and 100B. The electronic modules 100A and 100B each include the snubber circuit 18. It is thus possible to reduce or eliminate switching noise generated by the FETs 13A and 13B by using the respective snubber circuits 18.

A sharp noise waveform is superposed on an output waveform immediately after the switching power supply 200 is switched ON. Such a noise waveform can be made less sharp by using the second inductor L2 and the third inductor L3 of each of the electronic modules 100A and 100B and can be reduced or eliminated.

The switching power supply 200 uses the electronic module 100 of the first preferred embodiment as each of the electronic modules 100A and 100B. Fewer components are thus required for the switching power supply 200 and the area of the substrate 25 can be reduced. The manufacturing process is also simplified.

### Third Preferred Embodiment

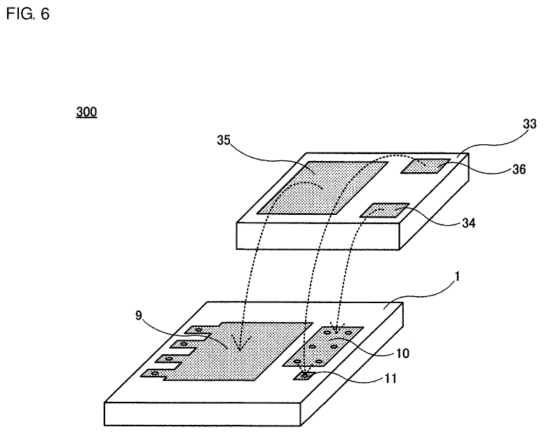

An electronic module 300 according to a third preferred embodiment of the present invention is shown in FIG. 6. FIG. 6 is an exploded perspective view of the electronic module 300 illustrating the state in which an FET 33 is separated from a multilayer substrate 1.

The electronic module 300 of the third preferred embodiment is an electronic module obtained by modifying a portion of the configuration of the electronic module 100 of the first preferred embodiment. In the electronic module 100, the drain electrode 14 of the FET 13 is connected to the first connecting electrode 9 of the multilayer substrate 1, the source electrode 15 of the FET 13 is connected to the second connecting electrode 10 of the multilayer substrate 1, and the gate electrode 16 of the FET 13 is connected to the third connecting electrode 11 of the multilayer substrate 1. In the electronic module 300, this configuration is changed. The FET 33 including terminal electrodes arranged differently from that of the FET 13 is used. A source electrode 35 of the FET 33 is connected to the first connecting electrode 9 of the multilayer substrate 1, a drain electrode 34 of the FET 33 is connected to the second connecting electrode 10 of the multilayer substrate 1, and a gate electrode 36 of the FET 33 is connected to the third connecting electrode 11 of the multilayer substrate 1. The configurations of the other components of the electronic module 300 are the same or substantially the same as those of the electronic module 100.

In this manner, the source electrode 35 of the FET 33 may be connected to the first connecting electrode 9, which also defines and functions as the first capacitor electrode, and the drain electrode 34 of the FET 33 may be connected to the second connecting electrode 10.

### Fourth Preferred Embodiment

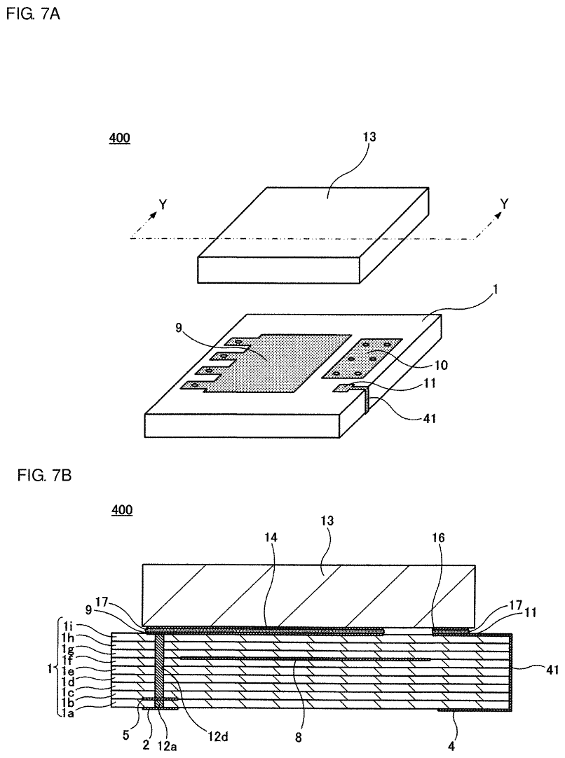

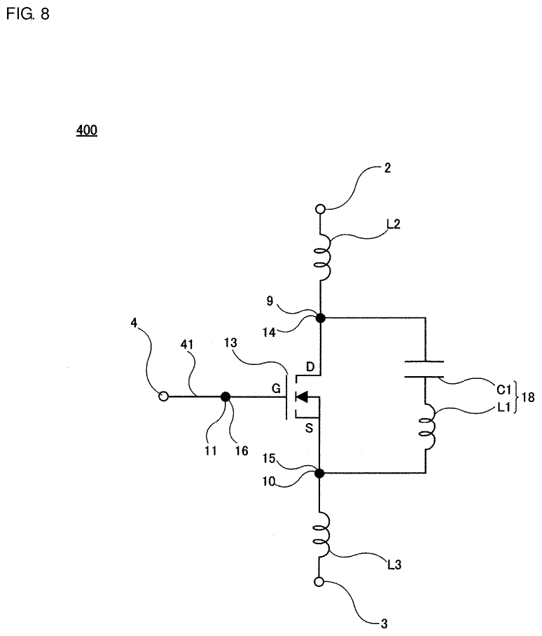

An electronic module 400 according to a fourth preferred embodiment of the present invention is shown in FIGS. 7A, 7B, and FIG. 8. FIG. 7A is an exploded perspective view of the electronic module 400. FIG. 7B is a sectional view of the electronic module 400 taken along the long dashed dotted line Y-Y in FIG. 7A. FIG. 8 is an equivalent circuit diagram of the electronic module 400.

The electronic module 400 of the fourth preferred embodiment is an electronic module obtained by modifying a portion of the configuration of the electronic module 100 of the first preferred embodiment. In the electronic module 100, the third connecting conductor connecting the third outer electrode 4 and the third connecting electrode 11 is defined by a conductive path linking the via-conductor 12c, the third relay electrode 7, and the via-conductor 12f provided within the multilayer substrate 1. This configuration is changed in the electronic module 400. The third connecting conductor connecting the third outer electrode 4 and the third connecting electrode 11 is defined by a wiring pattern 41 provided on a side surface of the multilayer substrate 1. The configurations of the other components of the electronic module 400 are the same or substantially the same as those of the electronic module 100.

In the electronic module 100, the via-conductors 12c and 12f defining the third connecting conductor pass through the substrate layers 1a through 1i, which are magnetic layers, and define a bead element. Because of this configuration, as shown in FIG. 4, the fourth inductor L4 is provided between the third outer electrode 4 and the third connecting electrode 11 in the electronic module 100. In contrast, in the electronic module 400, the wiring pattern 41 defining the third connecting conductor is provided on a side surface of the multilayer substrate 1, thus reducing or minimizing unwanted inductance components to be generated in the third connecting conductor. Nevertheless, the third connecting conductor inevitably has inductance components, though they are not many. At least, such inductance components are not those deliberately generated, and thus, an inductor is not shown between the third outer electrode 4 and the third connecting electrode 11 in FIG. 8.

A control signal to control the FET 13 is transmitted to the third connecting conductor. If the fourth inductor L4 (bead element) is provided in the third connecting conductor, such as in the electronic module 100, the control signal transmitted to the third connecting conductor is attenuated. In contrast, in the electronic module 400, a bead element is not provided in the third connecting conductor, and the control signal transmitted to the third connecting conductor is less likely to be attenuated.

### Fifth Preferred Embodiment

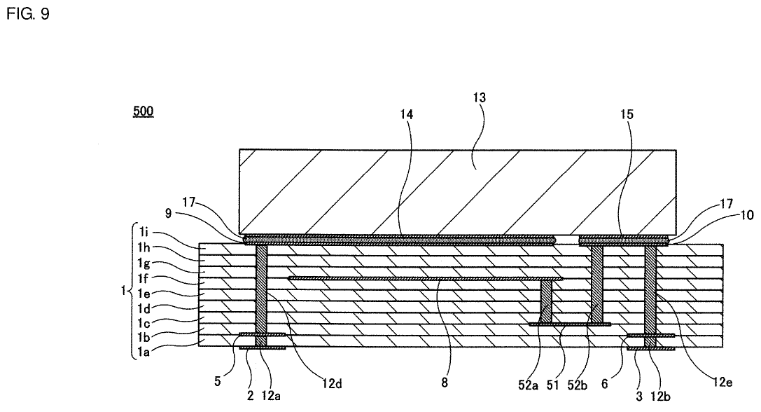

An electronic module 500 according to a fifth preferred embodiment of the present invention is shown in FIG. 9. FIG. 9 is a sectional view of the electronic module 500.

The electronic module 500 of the fifth preferred embodiment is an electronic module obtained by modifying a portion of the configuration of the electronic module 100 of the first preferred embodiment. In the electronic module 100, the first inductor L1 of the snubber circuit 18 is defined by the via-conductors 12g, which connect the second capacitor electrode 8 and the second connecting electrode 10, passing through the three substrate layers (magnetic layers) 1g through 1i. This configuration is changed in the electronic module 500. A fourth relay electrode 51 is provided on the upper main surface of the substrate layer 1b (or the lower main surface of the substrate layer 1c). The second capacitor electrode 8 and the fourth relay electrode 51 are connected to each other by a via-conductor 52a passing through the four substrate layers (magnetic layers) 1c through 1f. The fourth relay electrode 51 and the second connecting electrode 10 are connected to each other by a via-conductor 52b passing through the seven substrate layers (magnetic layers) 1c through 1i. The configurations of the other components of the electronic module 500 are the same or substantially the same as those of the electronic module 100.

In the electronic module 100, the first inductor L1 of the snubber circuit 18 is defined by the via-conductors 12g passing through the three substrate layers (magnetic layers) 1g through 1i. In the electronic module 500, the first inductor L1 is defined by the via-conductor 52a passing through the substrate layers (magnetic layers) 1c through 1f and the via-conductor 52b passing through the substrate layers (magnetic layers) 1c through 1i, that is, by the two via-conductors 52a and 52b passing through a total of eleven substrate layers. This configuration makes the conductive path of the first inductor L1 longer and increases the inductance value of the first inductor L1. Such a configuration is effective when a large inductance value is required for the first inductor L1.

### Sixth Preferred Embodiment

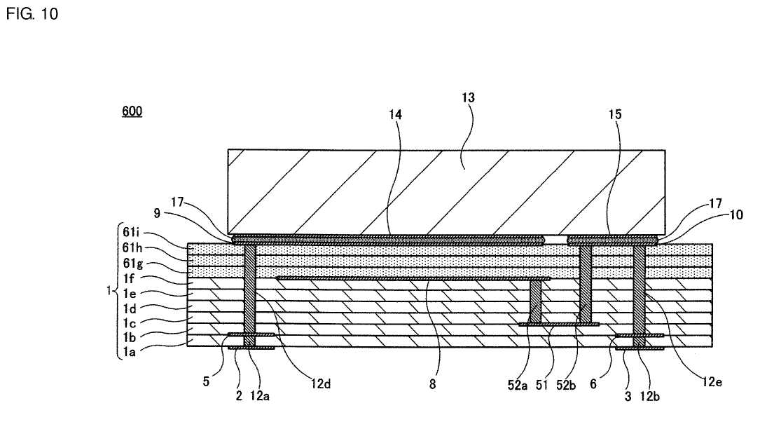

An electronic module 600 according to a sixth preferred embodiment of the present invention is shown in FIG. 10. FIG. 10 is a sectional view of the electronic module 600.

The electronic module 600 of the sixth preferred embodiment is an electronic module obtained by modifying a portion of the configuration of the electronic module 500 of the fifth preferred embodiment. In the electronic module 500, the multilayer substrate 1 includes nine substrate layers 1a through 1i, which are magnetic layers made of a magnetic material, stacked on each other. This configuration is changed in the electronic module 600. The upper three substrate layers are replaced by substrate layers 61g through 61i, which are dielectric layers made of a dielectric material. The configurations of the other components of the electronic module 600 are the same or substantially the same as those of the electronic module 500.

In the electronic module 600, the substrate layers 61g through 61i, which are dielectric layers having a high dielectric constant, are disposed between the first capacitor electrode (first connecting electrode 9) and the second capacitor electrode 8, which form the capacitor C1 of the snubber circuit 18. This configuration increases the electrostatic capacitance of the capacitor C1.

### Seventh Preferred Embodiment

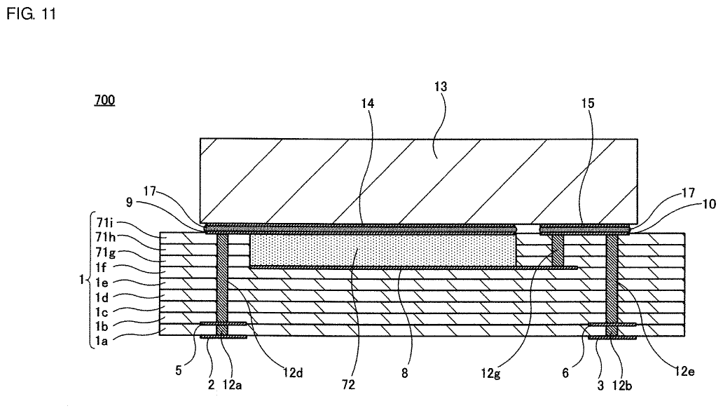

An electronic module 700 according to a seventh preferred embodiment of the present invention is shown in FIG. 11. FIG. 11 is a sectional view of the electronic module 700.

The electronic module 700 of the seventh preferred embodiment is an electronic module obtained by modifying a portion of the configuration of the electronic module 100 of the first preferred embodiment. In the electronic module 100, the multilayer substrate 1 includes nine substrate layers (magnetic layers) 1a through 1i stacked on each other. This configuration is changed in the electronic module 700. A notch is provided at the central portion of each of upper three layers (magnetic layers) 71g through 71i, and a dielectric material is disposed in the notches so as to define a dielectric member 72. The dielectric member 72 can be formed as follows. When preparing an unfired multilayer substrate 1 by stacking green sheets on each other, notches are formed in the green sheets corresponding to the substrate layers 71g through 71i. After the green sheets are stacked on each other, a dielectric material is provided in the notches, thus forming the dielectric member 72. The configurations of the other components of the electronic module 700 are the same or substantially the same as those of the electronic module 100.

In the electronic module 700, the dielectric member 72 is disposed between the first capacitor electrode (first connecting electrode 9) and the second capacitor electrode 8, thus increasing the electrostatic capacitance of the capacitor C1 of the snubber circuit 18.

### Eighth Preferred Embodiment

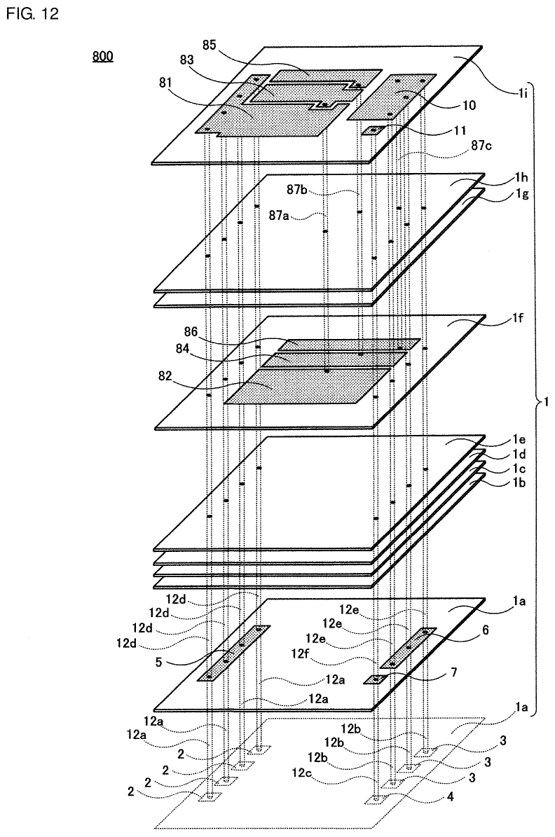

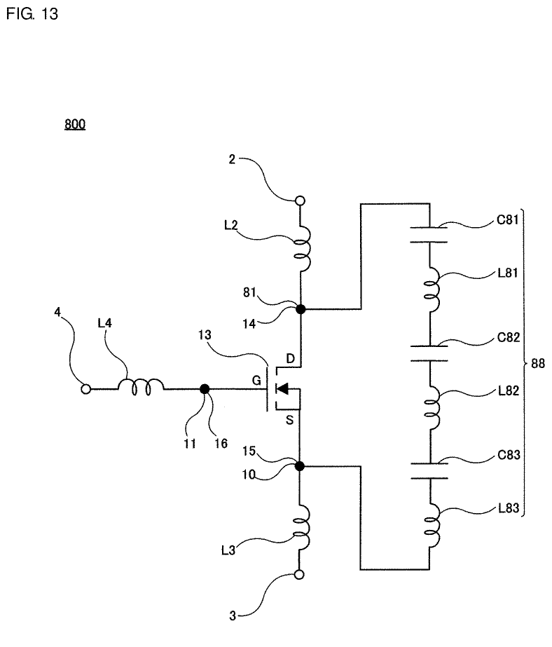

An electronic module 800 according to an eighth preferred embodiment of the present invention is shown in FIGS. 12 and 13. FIG. 12 is an exploded perspective view of the electronic module 800. FIG. 13 is an equivalent circuit diagram of the electronic module 800.

The electronic module 800 of the eighth preferred embodiment is an electronic module obtained by modifying a portion of the configuration of the electronic module 100 of the first preferred embodiment. In the electronic module 100, the second capacitor electrode 8 is provided on the upper main surface of the substrate layer 1f, and the first capacitor electrode (first connecting electrode 9) is provided on the upper main surface of the substrate layer 1i. The second capacitor electrode 8 and the second connecting electrode 10 are connected to each other by the via-conductors 12g. This configuration is changed in the electronic module 800. On the upper main surface of the substrate layer 1f, instead of the second capacitor electrode 8, a second capacitor electrode 82, a fourth capacitor electrode 84, and a sixth capacitor electrode 86 are provided. On the upper main surface of the substrate layer 1i, instead of the first capacitor electrode (first connecting electrode 9), a first capacitor electrode (first connecting electrode 81), a third capacitor electrode 83, and a fifth capacitor electrode 85 are provided. The second capacitor electrode 82 and the third capacitor electrode are connected to each other by a via-conductor 87a passing through the substrate layers 1g through 1i. The third capacitor electrode 83 and the fourth capacitor electrode 84 are connected to each other by a via-conductor 87b passing through the substrate layers 1g through 1i. The sixth capacitor electrode 86 and the second connecting electrode 10 are connected to each other by a via-conductor 87c passing through the substrate layers 1g through 1i. The configurations of the other components of the electronic module 800 are the same or substantially the same as those of the electronic module 100.

In the electronic module 800, the drain electrode 14 of the FET 13 is connected only to the first capacitor electrode (first connecting electrode 81) and is not connected to the third and fifth capacitor electrodes 83 and 85. The drain electrode 14 is provided on the lower main surface of the FET 13 such that it does not contact the third and fifth capacitor electrodes 83 and 85.

The electronic module 800 is represented by an equivalent circuit shown in FIG. 13. This will be explained more specifically. In the electronic module 800, a capacitor C81 is defined by electrostatic capacitance generated between the first capacitor electrode (first connecting electrode 81) and the second capacitor electrode 82, a capacitor C82 is defined by electrostatic capacitance generated between the third capacitor electrode 83 and the fourth capacitor electrode 84, and a capacitor C83 is defined by electrostatic capacitance generated between the fifth capacitor electrode 85 and the sixth capacitor electrode 86. In the electronic module 800, an inductor L81 is defined by the via-conductor 87a, an inductor L82 is defined by the via-conductor 87b, and an inductor L83 is defined by the via-conductor 87c. In the electronic module 800, the capacitor C81, the inductor L81, the capacitor C82, the inductor L82, the capacitor C83, and the inductor L83 are connected in series with each other so as to define a snubber circuit 88.

In the electronic module 800, it can be said that the fourth connecting conductor connecting the second capacitor electrode 82 and the second connecting electrode 10 is defined by the inductor L81, the capacitor C82, the inductor L82, the capacitor C83, and the inductor L83.

In this manner, as a result of changing the number, configuration, and positions of the capacitor electrodes, connecting electrodes, and via-conductors, the snubber circuit can be adjusted to have desired characteristics.

The electronic module 100 according to the first preferred embodiment, the switching power supply 200 according to the second preferred embodiment, and the electronic modules 300, 400, 500, 600, 700, and 800 according to the third through eighth preferred embodiments have been discussed above. However, the present invention is not restricted to the above-described preferred embodiments. Various modifications may be made in accordance with the gist of the present invention.

For example, in the electronic modules 100, 300, 400, 500, 600, 700, and 800, the FET 13 or 33 is used as the switching element. However, the switching element is not limited to an FET, and another type of switching element, such as a bipolar transistor, for example, may be used.

In the electronic modules 500 and 600, to increase the inductance value of the first inductor L1 of the snubber circuit 18, the fourth connecting conductor connecting the second capacitor electrode 8 and the second connecting electrode 10 is elongated as follows. The fourth relay electrode 51 is disposed on the upper main surface of the substrate layer 1b, and the second capacitor electrode 8 and the fourth relay electrode 51 are connected to each other by the via-conductor 52a, while the fourth relay electrode 51 and the second connecting electrode 10 are connected to each other by the via-conductor 52b. However, the fourth connecting conductor may be elongated by a different approach. Instead of or in addition to the above-described approach, a conductive line extending in the surface direction may be disposed between layers of the multilayer substrate 1 and be used as a portion of the fourth connecting conductor.

The switching power supply 200 is a DC-to-DC converter. However, the type of switching power supply is not restricted to a DC-to-DC converter, and may be another type of switching power supply, such as an AC-to-DC converter, for example.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An electronic module comprising:
a multilayer substrate including a plurality of substrate layers stacked on each other, first and second main surfaces opposing each other, and at least one side surface connecting the first and second main surfaces; and
a switching element including a plurality of terminal electrodes and being mounted on the second main surface of the multilayer substrate; wherein
first, second, and third outer electrodes are provided on the first main surface;
first, second, and third connecting electrodes are provided on the second main surface;
the first outer electrode and the first connecting electrode are electrically connected to each other by at least one first connecting conductor;
the second outer electrode and the second connecting electrode are electrically connected to each other by at least one second connecting conductor;
the third outer electrode and the third connecting electrode are electrically connected to each other by at least one third connecting conductor;
corresponding terminal electrodes of the switching element are connected to the first, second, and third connecting electrodes;
the first connecting electrode also defines and functions as a first capacitor electrode;
a second capacitor electrode is provided between corresponding layers of the substrate layers of the multilayer substrate;
a capacitor is defined by electrostatic capacitance generated between the first capacitor electrode and the second capacitor electrode;
the second capacitor electrode and the second connecting electrode are electrically connected to each other by at least one fourth connecting conductor;
an inductor is defined by the at least one fourth connecting conductor; and
the capacitor and the inductor define a snubber circuit.

2. The electronic module according to claim 1, wherein
at least one of the plurality of substrate layers is a magnetic layer made of a magnetic material; and
the at least one fourth connecting conductor passes through the magnetic layer.

3. The electronic module according to claim 1, wherein an area of the first connecting electrode, which also defines and functions as the first capacitor electrode, is larger than an area of the second connecting electrode and an area of the third connecting electrode.

4. The electronic module according to claim 1, wherein
the switching element is an FET including a drain electrode, a source electrode, and a gate electrode as the terminal electrodes;
the drain electrode is electrically connected to the first connecting electrode;
the source electrode is electrically connected to the second connecting electrode; and
the gate electrode is electrically connected to the third connecting electrode.

5. The electronic module according to claim 1, wherein
the switching element is an FET including a drain electrode, a source electrode, and a gate electrode as the terminal electrodes;
the source electrode is electrically connected to the first connecting electrode;
the drain electrode is electrically connected to the second connecting electrode; and
the gate electrode is electrically connected to the third connecting electrode.

6. The electronic module according to claim 1, wherein a length of the at least one fourth connecting conductor is greater than a distance between the first capacitor electrode and the second capacitor electrode.

7. The electronic module according to claim 2, wherein
the at least one first connecting conductor passes through the at least one magnetic layer; and
the at least one second connecting conductor passes through the at least one magnetic layer.

8. The electronic module according to claim 1, wherein the at least one third connecting conductor is provided on a corresponding side surface of the multilayer substrate so as to electrically connect the third outer electrode and the third connecting electrode.

9. The electronic module according to claim 1, wherein:
the multilayer substrate includes, as at least one of the plurality of substrate layers, at least one of a dielectric layer covering an entirety or substantially an entirety of a surface area of the multilayer substrate and a dielectric layer covering a portion of a surface area of the multilayer substrate; and
the dielectric layer included in the multilayer substrate is disposed between the first capacitor electrode and the second capacitor electrode which define the capacitor.

10. A switching power supply comprising:
a substrate; and
the electronic module according to claim 1 mounted on the substrate.

11. The switching power supply according to claim 10, wherein
at least one of the plurality of substrate layers is a magnetic layer made of a magnetic material; and
the at least one fourth connecting conductor passes through the magnetic layer.

12. The switching power supply according to claim 10, wherein an area of the first connecting electrode, which also defines and functions as the first capacitor electrode, is larger than an area of the second connecting electrode and an area of the third connecting electrode.

13. The switching power supply according to claim 10, wherein
the switching element is an FET including a drain electrode, a source electrode, and a gate electrode as the terminal electrodes;
the drain electrode is electrically connected to the first connecting electrode;
the source electrode is electrically connected to the second connecting electrode; and
the gate electrode is electrically connected to the third connecting electrode.

14. The switching power supply according to claim 10, wherein
the switching element is an FET including a drain electrode, a source electrode, and a gate electrode as the terminal electrodes;
the source electrode is electrically connected to the first connecting electrode;
the drain electrode is electrically connected to the second connecting electrode; and
the gate electrode is electrically connected to the third connecting electrode.

15. The switching power supply according to claim 10, wherein a length of the at least one fourth connecting conductor is greater than a distance between the first capacitor electrode and the second capacitor electrode.

16. The switching power supply according to claim 11, wherein
the at least one first connecting conductor passes through the at least one magnetic layer; and
the at least one second connecting conductor passes through the at least one magnetic layer.

17. The switching power supply according to claim 10, wherein the at least one third connecting conductor is provided on a corresponding side surface of the multilayer substrate so as to electrically connect the third outer electrode and the third connecting electrode.

18. The switching power supply according to claim 10, wherein:
the multilayer substrate includes, as at least one of the plurality of substrate layers, at least one of a dielectric layer covering an entirety or substantially an entirety of a surface area of the multilayer substrate and a dielectric layer covering a portion of a surface area of the multilayer substrate; and
the dielectric layer included in the multilayer substrate is disposed between the first capacitor electrode and the second capacitor electrode which define the capacitor.
